(19) United States
(12) Patent Application Publication
(10) Pub. No.: US 2024/0194843 A1
(43) Pub. Date: Jun. 13, 2024

(54) LIGHT EMITTING DISPLAY DEVICE

(71) Applicant: LG DISPLAY CO., LTD., SEOUL (KR)

(72) Inventors: Sungbin SHIM, Paju-si (KR); Sangpil PARK, Paju-si (KR)

(73) Assignee: LG DISPLAY CO., LTD., SEOUL (KR)

(21) Appl. No.: 18/239,300

(22) Filed: Aug. 29, 2023

(30) Foreign Application Priority Data
Dec. 9, 2022 (KR) 10-2022-0171719

(51) Int. Cl. H01L 33/62; H01L 25/075; H01L 25/16; H01L 33/38

(52) U.S. Cl. CPC H01L 33/62; H01L 25/0753; H01L 25/167; H01L 33/38

(57) ABSTRACT

A light emitting display device includes a substrate and a plurality of pixels disposed on the substrate, each of the pixels includes a first electrode at one portion of the pixel, an emission layer on the first electrode, a second electrode on the emission layer; an auxiliary electrode close to the first electrode in the pixel, and an auxiliary line connecting the auxiliary electrode and overlapping with a portion of the first electrode, and the auxiliary electrode is connected to the second electrode by penetrating the emission layer.

### CROSS-REFERENCE TO RELATED APPLICATION

This application claims the priority of Korean Patent Application No. 10-2022-0171719 filed on Dec. 9, 2022 which is hereby incorporated by reference in its entirety.

### BACKGROUND

### Field of the Disclosure

The present disclosure relates to a light emitting display device.

### Description of the Background

Among display device, a top emission type light emitting display device has a high aperture ratio and provides excellent display quality with high luminance versus power consumption. For the top emission type light emitting display device, the common electrode is formed of a transparent conductive material. Accordingly, in a large-area top emission type display device, sheet resistance of a common electrode should be lowered in order that a luminance difference does not occur over the entire surface area.

To lower the resistance of the common electrode, a structure in which an auxiliary line formed of a metal material having low electrical resistance is applied for electrically connecting to the common electrode may be required. In this case, structural improvement is required to reduce connection resistance while minimizing the area of the connection portion between the auxiliary line and the common electrode.

### SUMMARY

Accordingly, the present disclosure is directed to a light emitting display device that substantially obviates one or more of problems due to limitations and disadvantages described above.

More specifically, the present disclosure is to provide a top emission type light emitting display device or top emission type transparent light emitting display device having luminance compared to power consumption.

Additional features and advantages of the disclosure will be set forth in the description which follows and in part will be apparent from the description, or may be learned by practice of the disclosure. Other advantages of the present disclosure will be realized and attained by the structure particularly pointed out in the written description and claims hereof as well as the appended drawings.

Some aspects of the present disclosure may be directed to providing a top emission type light emitting display device or top emission type transparent light emitting display device having an auxiliary line for lowering the sheet resistance of a common electrode constituting a light emitting diode.

Some aspects of the present disclosure may be directed to providing a top emission type light emitting display device or top emission type transparent light emitting display device in which the area of a connection part for connecting a common electrode to an auxiliary line is minimized (or optimized) and contact resistance at the connection part is reduced.

To achieve these and other advantages and in accordance with the present disclosure, a light emitting display device includes a substrate; and a plurality of pixels disposed on the substrate. Each of the pixels includes: a first electrode at one portion of the pixel; an emission layer on the first electrode; a second electrode on the emission layer; an auxiliary electrode close to the first electrode in the pixel; and an auxiliary line connecting the auxiliary electrode and overlapping with a portion of the first electrode. The auxiliary electrode is connected to the second electrode by penetrating the emission layer.

In an example aspect, the auxiliary electrode includes: a line connection part connected to the auxiliary line; and an electrode connection part extended from the line connection part to one side of the auxiliary line, and connected to the second electrode.

In an example aspect, the electrode connection part has a polygonal band shape with a certain width.

In an example aspect, the electrode connection part includes a plurality of line segments branched from the line connection part in a first direction or a second direction.

In an example aspect, the plurality of line segments includes at least two segments running to the first direction; and a plurality of protrusions extruding from the segments in the second direction.

In an example aspect, one end portion of the auxiliary electrode is connected to the second electrode at the electrode connection part.

In an example aspect, the light emitting display device further comprises: a first lines running to a first direction on the substrate; a first insulating layer on the first lines; a second lines running to a second direction crossing the first direction on the first insulating layer; a thin film transistor connected to one of the first line and one of the second line on the first insulating layer; and a second insulating layer covering the first lines, the second lines and the thin film transistor. The first electrode is disposed on the second insulating layer and connected to the thin film transistor.

In an example aspect, the auxiliary line is one of the first lines. The auxiliary electrode is formed of same material on same layer of any one of a gate electrode, a source electrode and a drain electrode. The auxiliary electrode in connected to the auxiliary line via a contact hole penetrating the first insulating layer.

In an example aspect, the emission layer and the second electrode are commonly disposed over the plurality of the pixels. The auxiliary electrode is connected to the second electrode by penetrating the second insulating layer and the emission layer.

In an example aspect, the substrate has a transparent material. Each of the plurality of pixels includes: an emission area overlapping with the first electrode; and a transmissive area around the first electrode.

In an example aspect, the emission layer and the second electrode are disposed at the emission area and the transmissive area. The auxiliary electrode is disposed at the transmissive area and is connected to the second electrode by penetrating the emission layer at the transmissive area.

In an example aspect, the emission area further includes a thin film transistor disposed under the first electrode and connected to the first electrode. The transmissive area passes through lights incident from a lower side of the substrate to an upper side of the substrate.

In another aspect of the present disclosure, a light emitting display device includes a substrate; an auxiliary line on the substrate; a first insulating layer on the auxiliary line; an auxiliary electrode overlapping with a portion of the auxiliary line on the first insulating layer; a second insulating layer on the auxiliary electrode; a first electrode disposed on the second insulating layer, the first electrode not overlapping with the auxiliary electrode; an emission layer on the first electrode; and a second electrode on the emission layer, the second electrode covering the auxiliary line and the auxiliary electrode. An end portion of the auxiliary electrode not overlapping with the auxiliary line is connected to the second electrode by penetrating the second insulating layer and the emission layer.

In an example aspect, the light emitting display device further comprises: a planarization layer disposed between the second insulating layer and the first electrode, and not overlapping with the auxiliary electrode.

In an example aspect, the light emitting display device further comprises: a bank covering circumference area of the first electrode on the planarization layer, and not being overlapping with the auxiliary electrode.

In an example aspect, the light emitting display device further comprises: a light emitting element including: the first electrode exposed by the bank; the emission layer on the first electrode; and the second electrode on the emission layer and the first electrode.

In an example aspect, the auxiliary electrode includes a plurality of segments. Edges of the plurality of segments are melted and connected to the second electrode.

The light emitting display device according to the present disclosure has a structure in which an auxiliary line having low electric resistance is connected to a common electrode, and thus provides excellent display quality without luminance deviation over a large area.

In an example aspect, the light emitting display device according to the present disclosure ensure an optimum (or minimum) area and a higher aperture ratio by having a melting contact structure using a laser at a portion where a common electrode and an auxiliary line for lowering the electric resistance of the common electrode are connected.

In an example aspect, the light emitting display device according to the present disclosure has a structure in which the contact resistance may be reduced by increasing an effective contact area of connection parts or a number of contact points between the auxiliary line and the common electrode using a branching structure of the auxiliary line. As a result, a large area light emitting display device having low power consumption and high luminance is provided.

In addition to the effects of the present disclosure mentioned above, other features and advantages of this specification are described below, or may be clearly understood by those skilled in the art from such description or explanation.

### BRIEF DESCRIPTION OF THE DRAWINGS

The accompanying drawings, which are included to provide a further understanding of the disclosure and are incorporated in and constitute a part of this application, illustrate aspects of the disclosure and together with the description serve to explain the principle of the disclosure.

In the drawings:

FIG. 1 is a plan view illustrating a schematic structure of a light emitting display device according to the present disclosure;

FIG. 2 is a circuit diagram illustrating a structure of one pixel disposed in a light emitting display device according to the present disclosure;

FIG. 3 is an enlarged plan view illustrating a structure of one pixel disposed in the light emitting display device according to a first aspect of the present disclosure;

FIG. 4 is a cross-sectional view, along cutting line I-I′ in FIG. 3, illustrating a structure of one pixel according to the first aspect of the present disclosure;

FIG. 5 is a cross-sectional view, along cutting line II-II′ in FIG. 3, illustrating a structure of a connection part between a common electrode and an auxiliary electrode in the light emitting display device according to the first aspect of the present disclosure;

FIG. 6 is an enlarged plan view illustrating a structure of one pixel disposed in a light emitting display device according to a second aspect of the present disclosure;

FIG. 7 is a cross-sectional view, along cutting line III-III′ in FIG. 6, illustrating a structure of one pixel in the light emitting display device according the second aspect of the present disclosure;

FIG. 8 is a plan view, along cutting line IV-IV′ in FIG. 6, illustrating a structure of a connection part between a common electrode and an auxiliary electrode in the light emitting display device according to the second aspect of the present disclosure; and

FIGS. 9A to 9C are plan views illustrating various shapes of auxiliary electrodes in the light emitting display device according to the present disclosure.

### DETAILED DESCRIPTION

Advantages and features of the present disclosure, and implementation methods thereof will be clarified through following aspects described with reference to the accompanying drawings. The present disclosure may, however, be embodied in different forms and should not be construed as limited to the aspects set forth herein. Rather, these example aspects are provided so that this disclosure may be sufficiently thorough and complete to assist those skilled in the art to fully understand the scope of the present disclosure. Further, the protected scope of the present disclosure is defined by claims and their equivalents.

The shapes, sizes, ratios, angles, numbers, and the like, which are illustrated in the drawings to describe various example aspects of the present disclosure, are merely given by way of example. Therefore, the present disclosure is not limited to the illustrated details. Like reference numerals refer to like elements throughout the specification unless otherwise specified. In the following description, where the detailed description of the relevant known function or configuration may unnecessarily obscure an important point of the present disclosure, a detailed description of such known function of configuration may be omitted.

Reference will now be made in detail to the exemplary aspects of the present disclosure, examples of which are illustrated in the accompanying drawings. Wherever possible, the same reference numbers will be used throughout the drawings to refer to the same or like parts. In the specification, it should be noted that like reference numerals already used to denote like elements in other drawings are used for elements wherever possible. In the following description, when a function and a configuration known to those skilled in the art are irrelevant to the essential configuration of the present disclosure, their detailed descriptions will be omitted. The terms described in the specification should be understood as follows.

In the present specification, where the terms “comprise,” “have,” “include,” and the like are used, one or more other elements may be added unless the term, such as “only,” is used. An element described in the singular form is intended to include a plurality of elements, and vice versa, unless the context clearly indicates otherwise.

In construing an element, the element is construed as including an error or tolerance range even where no explicit description of such an error or tolerance range is provided.

In the description of the various aspects of the present disclosure, where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third layer or element may be interposed therebetween. Also, if a first element is described as positioned “on” a second element, it does not necessarily mean that the first element is positioned above the second element in the figure. The upper part and the lower part of an object concerned may be changed depending on the orientation of the object. Consequently, where a first element is described as positioned “on” a second element, the first element may be positioned “below” the second element or “above” the second element in the figure or in an actual configuration, depending on the orientation of the object.

In describing a temporal relationship, when the temporal order is described as, for example, “after,” “subsequent,” “next,” or “before,” a case which is not continuous may be included unless a more limiting term, such as “just,” “immediate(ly),” or “direct(ly),” is used.

It will be understood that, although the terms “first,” “second,” and the like may be used herein to describe various elements, these elements should not be limited by these terms as they are not used to define a particular order. These terms are used only to distinguish one element from another. For example, a first element could be termed a second element, and, similarly, a second element could be termed a first element, without departing from the scope of the present disclosure.

In describing various elements in the present disclosure, terms such as first, second, A, B, (a), and (b) may be used. These terms are used merely to distinguish one element from another, and not to define a particular nature, order, sequence, or number of the elements. Where an element is described as being “linked”, “coupled,” or “connected” to another element, that element may be directly or indirectly connected to that other element unless otherwise specified. It is to be understood that additional element or elements may be “interposed” between the two elements that are described as “linked,” “connected,” or “coupled” to each other.

It should be understood that the term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

Features of various aspects of the present disclosure may be partially or overall coupled to or combined with each other, and may be variously inter-operated with each other and driven technically as those skilled in the art may sufficiently understand. The aspects of the present disclosure may be carried out independently from each other, or may be carried out together in a co-dependent relationship.

Hereinafter, an example of a display apparatus according to the present disclosure will be described in detail with reference to the attached drawings. Wherever possible, the same reference numbers will be used throughout the drawings to refer to the same or like parts.

Hereinafter, referring to the attached figures, the present disclosure will be explained. Since a scale of each of elements shown in the accompanying drawings may be different from an actual scale for convenience of description, the present disclosure is not limited to the scale shown in the drawings.

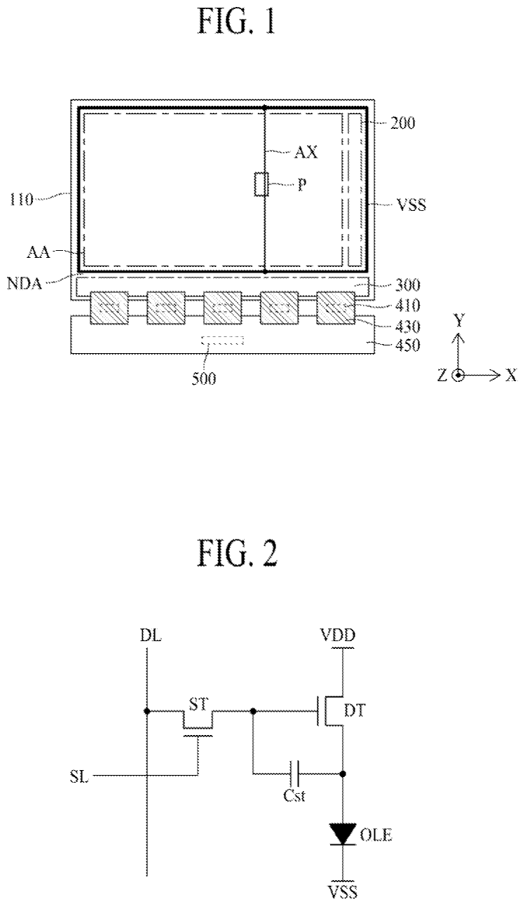

FIG. 1 is a plan view illustrating a schematic structure of a light emitting display device according to the present disclosure. In FIG. 1, X-axis refers to the direction parallel to the scan line, Y-axis refers to the direction of the data line, and Z-axis refers to the height direction of the display device.

Referring to FIG. 1, the electroluminescence display comprises a substrate 110, a gate (or scan) driver 200, a data pad portion 300, a source driving IC (i.e., integrated circuit) 410, a flexible circuit film 430, a circuit board 450, and a timing controller 500.

The substrate 110 may include an electrical insulating material or a flexible material. The substrate 110 may be made of a glass, a metal or a plastic, but it is not limited thereto. When the light emitting display device is a flexible display, the substrate 110 may be made of the flexible material such as plastic. For example, the substrate 110 may include a transparent polyimide material.

The substrate 110 may include a display area AA and a non-display area NDA. The display area AA, which is an area for representing the video images, may be defined as the majority middle area of the substrate 110, but it is not limited thereto. In the display area AA, a plurality of pixels P are arranged in a matrix manner. Further, scan lines (or gate lines) and data lines are disposed on the substrate 110. Each pixel P is disposed in an area where the scan lines running along the X-axis and the data lines running along the Y-axis intersect. In addition, an auxiliary line AX extending along the Y-axis may be disposed at one side of a group of some pixels P. Here, the pixel P may represent any one color among red, green and blue or red, green, blue and white. A unit pixel may be configured by gathering a red pixel, a green pixel and a blue pixel, or by gathering a red pixel, a green pixel, a blue pixel and a white pixel.

The non-display area NDA, which is an area not representing the video images, may be defined at the circumference areas of the substrate 110 surrounding all or some of the display area AA. In the non-display area NDA, a low voltage line VSS, the gate driver 200 and the data pad portion 300 may be formed or disposed.

The gate driver 200 may supply the scan (or gate) signals to the scan lines according to the gate control signal received from the timing controller 500 through the pad portion 300. The gate driver 200 may be formed at the non-display area NDA at any one outside edge portion of the display area DA on the substrate 110, as a GIP (Gate driver In Panel) type. GIP type means that the gate driver 200 is directly formed on the substrate 110. For example, the gate driver 200 may be configured with shift registers. In the GIP type, the transistors for shift registers of the gate driver 200 are directly formed on the upper surface of the substrate 110.

The pad portion 300 may be disposed in the non-display area NDA at one side edge of the display area AA of the substrate 110. The pad portion 300 may include data pads connected to each of the data lines, driving current pads connected to the driving current lines, a high-potential pad receiving a high potential voltage, and a low-potential pad receiving a low potential voltage.

The auxiliary line AX extending along Y-axis in the display area AA is connected to a low potential line VSS disposed in the non-display area NDA as being adjacent to the display area AA and surrounding the display area AA. For example, the auxiliary line AX has one end connected to a low potential line VSS disposed in the non-display area NDA adjacent to the upper side of the display area AA, and the other end connected to the low potential line VSS disposed in the non-display area NDA adjacent to the lower side of the display area AA. The low potential line adjacent to the upper side of the display area AA and the low potential line adjacent to the lower side of the display area AA may be connected through a low potential line disposed adjacent to the left side and/or the right side of the display area AA.

The source driving IC 410 may receive the digital video data and the source control signal from the timing controller 500. The source driving IC 410 may convert the digital video data into the analog data voltages according to the source control signal and then supply that to the data lines. When the source driving IC 410 is made as a chip type, it may be installed on the flexible circuit film 430 as a COF (Chip On Film) or COP (Chip On Plastic) type.

The flexible circuit film 430 may include a plurality of first link lines connecting the pad portion 300 to the source driving IC 410, and a plurality of second link lines connecting the pad portion 300 to the circuit board 450. The flexible circuit film 430 may be attached on the pad portion 300 using an anisotropic conducting film, so that the pad portion 300 may be connected to the first link lines of the flexible circuit film 430.

The circuit board 450 may be attached to the flexible circuit film 430. The circuit board 450 may include a plurality of circuits implemented as the driving chips. For example, the circuit board 450 includes a timing controller 500. The circuit board 450 may be a printed circuit board or a flexible printed circuit board.

The timing controller 500 may receive the digital video data and the timing signal from an external system board through the line cables of the circuit board 450. The timing controller 500 may generate a gate control signal for controlling the operation timing of the gate driver 200 and a source control signal for controlling the source driving IC 410, based on the timing signal. The timing controller 500 may supply the gate control signal to the gate driver 200 and supply the source control signal to the source driving IC 410. Depending on the product types, the timing controller 500 may be formed as one chip with the source driving IC 410 and mounted on the substrate 110.

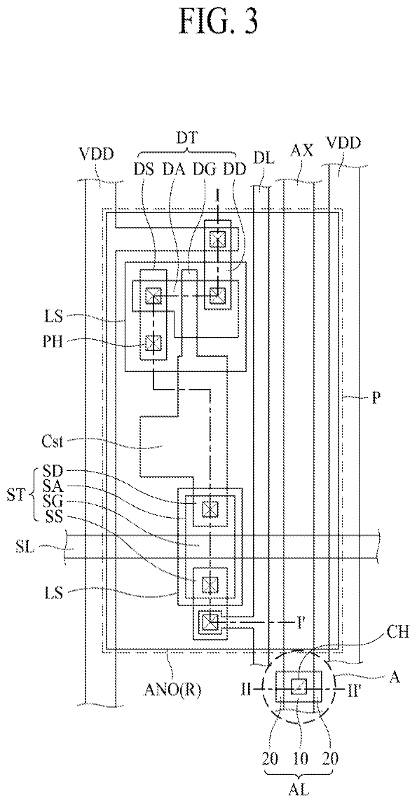

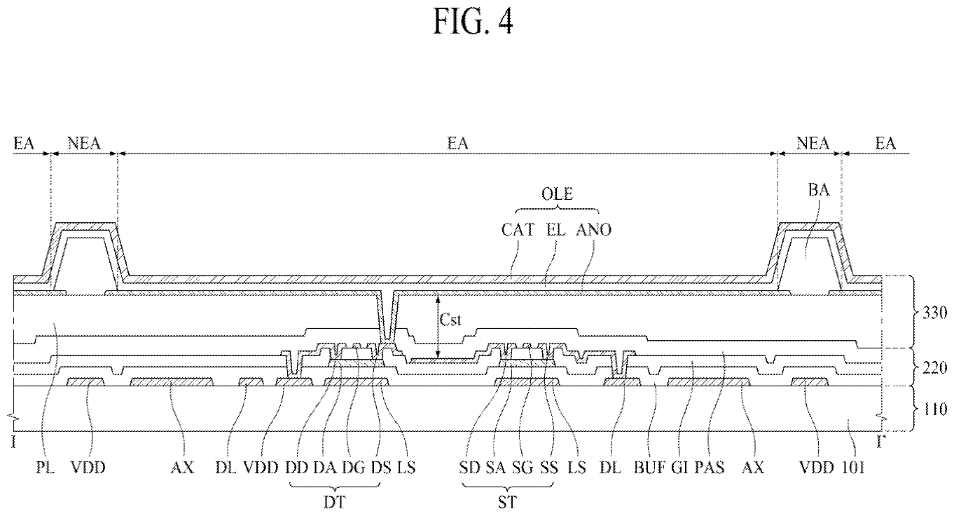

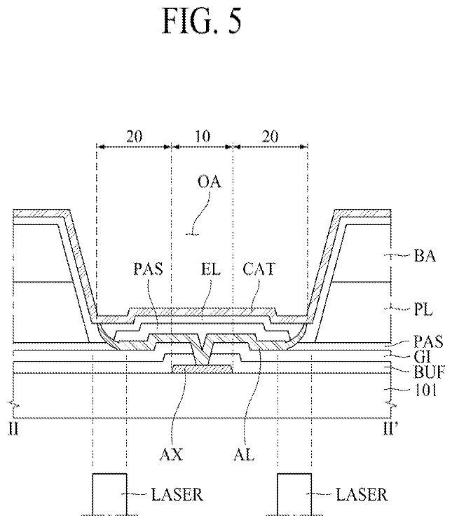

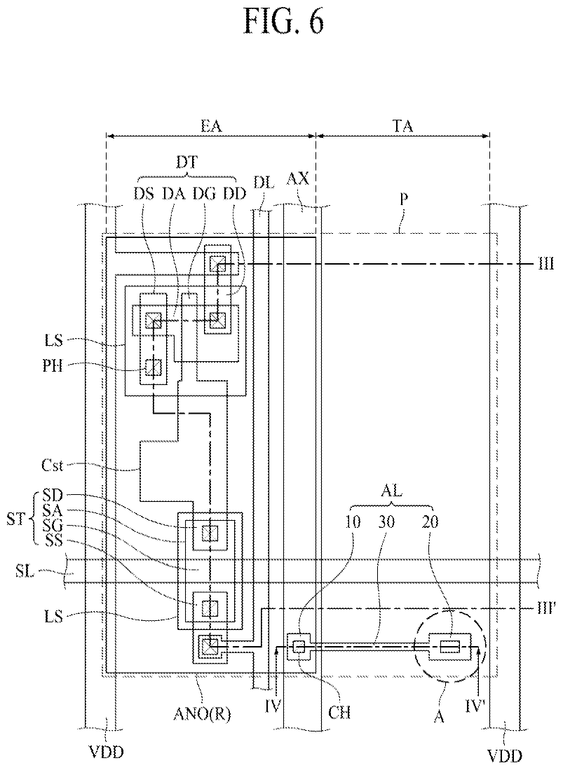

Hereinafter, referring to FIGS. 2 to 5, a first aspect of a light emitting display device according to a first aspect of the present disclosure will be explained. FIG. 2 is a circuit diagram illustrating a structure of one pixel disposed in a light emitting display device according to the present disclosure. FIG. 3 is an enlarged plan view illustrating a structure of one pixel disposed in the light emitting display device according to a first aspect of the present disclosure. FIG. 4 is a cross-sectional view, along cutting line I-I′ in FIG. 3, illustrating a structure of one pixel according to the first aspect of the present disclosure. FIG. 5 is a cross-sectional view, along cutting line II-II′ in FIG. 3, illustrating a structure of a connection part between a common electrode and an auxiliary electrode in the light emitting display device according to the first aspect of the present disclosure.

Referring to FIGS. 2 to 4, each pixel P of the light emitting display may be defined by a scan line SL, a data line DL and a driving current line VDD. Each pixel P of the light emitting display may include a switching thin film transistor ST, a driving thin film transistor DT, a light emitting diode OLE and a storage capacitance Cst. The driving current line VDD may be supplied with a high-level voltage for driving the light emitting diode OLE.

A switching thin film transistor ST and a driving thin film transistor DT may be formed on a substrate 110. For example, the switching thin film transistor ST may be configured to be connected to the scan line SL and the data line DL is crossing. The switching thin film transistor ST may include a gate electrode SG, a semiconductor layer SA, a source electrode SS and a drain electrode SD. The gate electrode SG may be a part of the scan line SL. The semiconductor layer SA may be disposed as crossing the gate electrode SG. The overlapping portion of the semiconductor layer SA with the gate electrode SG may be defined as the channel area. The source electrode SS may be connected to or branched from the data line DL, and the drain electrode SD may be connected to the driving thin film transistor DT. The source electrode SS may be one side of the semiconductor layer SA from the channel area, and the drain electrode SD may be the other side of the semiconductor layer SA. By supplying the data signal to the driving thin film transistor DT, the switching thin film transistor ST may play a role of selecting a pixel which would be driven.

The driving thin film transistor DT may play a role of driving the light diode OLE of the selected pixel by the switching thin film transistor ST. The driving thin film transistor DT may include a gate electrode DG, a semiconductor layer DA, a source electrode DS and a drain electrode DD. The gate electrode DG of the driving thin film transistor DT may be connected to the drain electrode SD of the switching thin film transistor ST. For example, the gate electrode DG of the driving thin film transistor DT may be connected to the drain electrode SD of the switching thin film transistor ST. In the driving thin film transistor DT, the drain electrode DD may be connected to the driving current line VDD, further, the source electrode DS may be connected to the anode electrode (or pixel electrode) ANO of the light emitting diode (or light emitting element) OLE. The semiconductor layer DA may be disposed as crossing over the gate electrode DG. In the semiconductor layer DA, the overlapping portion with the gate electrode DG may be defined as a channel area. The source electrode DS may be connected at one side of the semiconductor layer DA around the channel area, and the drain electrode DD is connected to the other side of the semiconductor layer DA. A capacitor (or storage capacitance) Cst may be disposed between the gate electrode DG of the driving thin film transistor DT and the anode electrode ANO of the light emitting diode OLE.

The light emitting diode OLE may generate light according to the current controlled by the driving thin film transistor DT. The driving thin film transistor DT may control the amount of current flowing from the driving current ling VDD to the light emitting diode OLE according to the voltage difference between the gate electrode DG and the source electrode DS.

The light emitting diode OLE may include an anode electrode ANO, an emission layer EL, and a cathode electrode CAT. The light emitting diode OLE may emit lights according to the current controlled by the driving thin film transistor DT. In other words, the light emitting diode OLE may provide an image by emitting light according to the current controlled by the driving thin film transistor DT. The anode electrode ANO of the light emitting diode OLE may be connected to the source electrode DS of the driving thin film transistor DT. The cathode electrode CAT (or, common electrode) may be low-power line VSS supplied with the low-potential voltage. Therefore, the light emitting diode OLE may be driven by the electric current flown from the driving current line VDD to the low power line VSS controlled by the driving thin film transistor DT.

A plurality of pixels P may be arrayed on the substrate 110. For example, along the horizontal direction, a red pixel, a green pixel and a blue pixel may be sequentially arrayed or disposed. The combination of the red pixel, the green pixel and the blue pixel may configure one unit pixel. In other case, each of the red pixel, the green pixel and the blue pixel may be called as ‘sub-pixels’, and these combinations of sub-pixels may be called as a ‘pixel’. For another example, a red pixel, a green pixel, a white pixel and a blue pixel are sequentially disposed along the horizontal direction. The red pixel, the green pixel, the white pixel and the blue pixel may form one ‘unit pixel’. In FIG. 3, one of pixel P is illustrated.

Further referring to FIG. 4, a cross-sectional structure of the light emitting display device according to the present disclosure will be explained. A light emitting display device may include a substrate 110, a driving element layer 220 and a light emitting element layer 330. The driving element layer 220 may include a plurality of thin layers formed on the substrate 110. The driving element layer 220 may include a switching thin film transistor ST and a driving thin film transistor DT.

On the substrate 110, a data line DL, a driving current line VDD, an auxiliary line AX and a light shielding layer LS may be formed. The light shielding layer LS may be disposed in an island shape spaced apart from the data line DL and the driving current ling VDD by a predetermined distance and overlapping with the semiconductor layers SA and DA.

A buffer layer BUF is deposited on entire surface of the substrate 110 as covering the data line DL, the driving current line VDD, the auxiliary line AX and the light shielding layer LS. In detail, on the buffer layer BUF, the semiconductor layer SA of the switching thin film transistor ST and the semiconductor layer DA of the driving thin film transistor DT are formed. The channel areas in the semiconductor layers SA and DA may overlap with the light shielding layer LS.

A gate insulating layer GI is deposited on the substrate 110 as covering the semiconductor layers SA and DA. A gate electrode SG overlapping with the semiconductor layer SA of the switching thin film transistor ST and the gate electrode DG overlapping with the semiconductor layer DA of the driving thin film transistor DT are formed on the gate insulating layer GI. In addition, at both sides of the gate electrode SG of the switching thin film transistor ST, a source electrode SS contacting one side of the semiconductor layer SA while being spaced apart from the gate electrode SG, and a drain electrode SD contacting the other side of the semiconductor layer SA are formed. Further, at both sides of the gate electrode DG of the driving thin film transistor DT, a source electrode DS contacting one side of the semiconductor layer DA while being spaced apart from the gate electrode DG, and a drain electrode DD contacting the other side of the semiconductor layer DA are formed.

The gate electrodes SG and DG and the source-drain electrodes SS-SD and DS-DD are formed on the same layer, but are spatially and electrically separated from each other. The source electrode SS of the switching thin film transistor ST may be connected to the data line DL via a contact hole penetrating the gate insulating layer GI. Further, the drain electrode DD of the driving thin film transistor DT may be connected to the driving current line VDD via another contact hole penetrating the gate insulating layer.

A passivation layer PAS is deposited on the substrate 110 as covering the thin film transistors ST and DT. The passivation layer PAS may be made of an inorganic material such as silicon oxide or silicon nitride.

The light emitting element layer 330 is formed on the driving element layer 220. The light emitting element layer 330 may include a light emitting diode OLE. Before forming the light emitting diode OLE, a planarization layer PL may be deposited on the passivation layer PAS. The surface of the substrate 110 on which the thin film transistors ST and DT are formed is not uniform or even, so the planarization layer PL is a thin film for flattening the uneven surface condition. To make the height difference being even, the planarization layer PL may be formed of an organic material. A pixel contact hole PH exposing a part of the source electrode DS of the driving thin film transistor DT is formed in the passivation layer PAS and the planarization layer PL.

The anode electrode ANO is formed on the top surface of the planarization layer PL. The anode electrode ANO connects to the source electrode DS of the driving thin film transistor DT via the pixel contact hole PH. The anode electrode ANO may have different structure and configuring elements according to the emission type of the light emitting diode OLE. For example, in the case of a bottom emission type that provides lights in the direction of the substrate 110, it may be formed of a transparent conductive material. For another example, in the case of a top emission type that provides lights in the upward direction facing the substrate 110, it may be formed of a metal material having excellent light reflectance. Since the present disclosure relates to the top emission type display device, the anode electrode ANO may include a metal material.

A bank BA is formed on the top surface of the substrate 110 having the anode electrode ANO. The bank BA may be an insulating film made of an inorganic material or an organic material. Here, a case made of an organic material will be described. The bank BA covers the edge parts of the anode electrode ANO, exposing most of the central area of the anode electrode ANO. The area not covered by the bank BA is defined as the emission area EA, and the area where the bank BA is formed is defined as the non-emission area NEA.

An emission layer EL is disposed on the anode electrode ANO and bank BA. The emission layer EL may be deposited on entire of the display area AA of the substrate 110 as covering the anode electrode ANO and the bank BA. For an aspect, the emission layer EL may include at least two emission parts for generating white light. For example, the emission layer EL may include a first emission part and a second emission part vertically stacked for generating white light by mixing the first light from the first emission part and the second light from the second emission part.

For another example, the emission layer EL may include any one of a blue emission part, a green emission part, and a red emission part for generating light corresponding to a color set in each pixel. Further, the light emitting diode OLE may include a functional layer for improving light emitting efficiency and/or lifetime of the emission layer EL.

A cathode electrode CAT is deposited on the entire surface of the substrate 110 on which the emission layer is formed. The cathode electrode CAT is deposited to make surface contact with the emission layer EL. The cathode electrode CAT is formed over the entire substrate 110 to be commonly connected to the emission layer EL deposited in all pixels. In the case of the top emission type, the cathode electrode CAT may include a transparent conductive material. For example, the cathode electrode CAT may be made of an oxide material including indium, i.e., a transparent conductive material such as indium-tin-oxide (ITO) or indium-zinc-oxide (IZO).

In the top emission type, the metal oxide, which is a transparent conductive material configuring the cathode electrode CAT, has a sheet resistance considerably higher than that of the metal material. Therefore, when the area of the cathode electrode CAT is large, such as in a large-area TV having 40 inch or more of diagonal length, the level of low voltage may not be uniformly distributed over the entire area due to the high sheet resistance of the transparent conductive material. This may cause luminance non-uniformity and is an important reason for deterioration of image quality.

To solve this issue, a structure for lowering the resistance of the cathode electrode CAT is required. The auxiliary line AX is an element for lowering the resistance of the cathode electrode CAT. The auxiliary line AX may be formed first on the surface of the substrate 110, and the cathode electrode CAT may be formed last after other layers are formed. Therefore, an element for connecting the auxiliary line AX and the cathode electrode CAT is required.

Referring to FIGS. 3 and 5, a structure of the auxiliary electrode AL, which is an element for connecting the auxiliary line AX and the cathode electrode CAT, and a structure of the connection area A will be explained. The auxiliary line AX is disposed parallel to the data line DL at one side of the pixel P. The auxiliary line AX does not need to be arranged for each pixel P. For example, one auxiliary line AX may be disposed for every 3, 6 or 12 columns of pixels P in the horizontal direction. As shown in FIG. 3, the auxiliary line AX may overlap with the pixel P and may be disposed between the data line DL and the driving current line VDD. For another example, the auxiliary line AX may be disposed outside the driving current line VDD.

A buffer layer BUF and a gate insulating layer GI are sequentially deposited on the auxiliary line AX as covering entire surface of the substrate 110. A contact hole CH exposing portions of the auxiliary line AX is formed at the gate insulating layer GI and the buffer layer BUF. An auxiliary electrode AL is formed on the gate insulating layer GI. The auxiliary electrode AL may be formed to cross the auxiliary line AX with a width wider than that of the auxiliary line AX. For example, the auxiliary electrode AL may include a line connection part 10 and an electrode connection part 20. The line connection part 10 is a portion overlapping with the auxiliary line AX. The electrode connection part 20 is a portion extending to both sides of the auxiliary line AX from the line connection part 10 and does not overlap with the auxiliary line AX. A part of the line connection part 10 of the auxiliary electrode AL is in physical and electrical contact with the auxiliary line AX through the contact hole CH.

The auxiliary electrode AX may be formed of the same material on the same layer as the gate electrode SG and DG, and/or the source-drain electrodes SS-SD and DS-DD. A passivation layer PAS is deposited on the auxiliary electrode AL. A planarization layer PL is deposited on the passivation layer PAS. The portion where the auxiliary electrode AL is formed may be patterned and removed, that is, the portion of the planarization layer PL covering the connection parts 10 and 20.

An anode electrode ANO is formed on the planarization layer PL. The auxiliary electrode AL is disposed adjacent to the anode electrode ANO but apart from the anode electrode ANO with a predetermined distance. Therefore, the anode electrode ANO is not formed over the auxiliary electrode AL, so that the anode electrode ANO does not overlap with the auxiliary electrode AL.

A bank BA is formed on the anode electrode ANO. Portions of the bank BA where the auxiliary electrode AL is formed may be patterned or remover. As a result, the planarization layer PL and the bank BA may have an opening OA exposing the auxiliary electrode AL.

An emission layer EL is deposited on the bank BA. The emission layer EL is commonly deposited over whole pixels P disposed on the substrate 110. Therefore, the emission layer EL is deposited at the opening OA exposing the auxiliary electrode AL. The emission layer EL is stacked on the auxiliary electrode AL.

A cathode electrode CAT is deposited on the emission layer EL. The cathode electrode CAT is also commonly deposited over the entire pixels P disposed on the substrate 110. Therefore, the cathode electrode CAT is stacked on the auxiliary electrode AL.

By irradiating a laser beam LASER on the connection part under this state, the auxiliary electrode AL is connected to the cathode electrode CAT. Here, the laser to the edge portions of the auxiliary electrode AL may be irradiated. Adjusting the thickness of the auxiliary electrode AL, the passivation layer PAS stacked on the edge of the auxiliary electrode AL may be deposited thinner than other portions. As a result, a seam portion in which the passivation layer PAS stacked on the stepped portion of the auxiliary electrode AL is relatively thinner than other portions is formed.

With this condition, when a laser is irradiated to the edge portions of the auxiliary electrode AL, the end portions of the auxiliary electrode AL melted by the laser, even having a low energy, passes through the passivation layer PAS and the light emitting layer EL in sequence, and then the auxiliary electrode AL may be connected to the cathode electrode CAT. For example, even when a laser having a low power, for example, having a wavelength of 532 nm or 1064 nm wavelength is irradiated, edge portions of the auxiliary electrode AL may be melted and connected to the cathode electrode CAT. At that time, the laser may be irradiated only to both end portions of the auxiliary electrode AL, or may be scanned from one end portion to the other end portion of the auxiliary electrode AL. Since the line connection part 10 of the auxiliary electrode AL is not to be melted, the scanning process may be performed with high speed, thus the manufacturing tack time may be shortened.

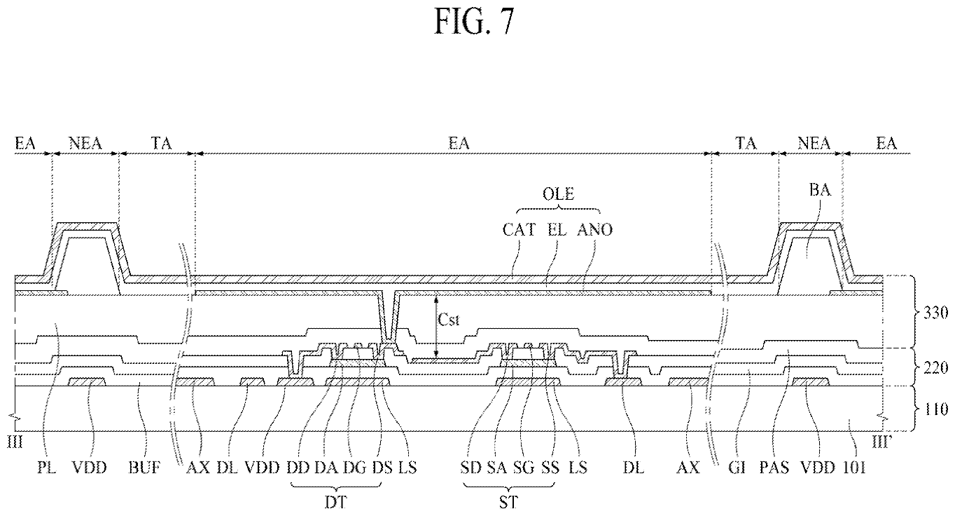

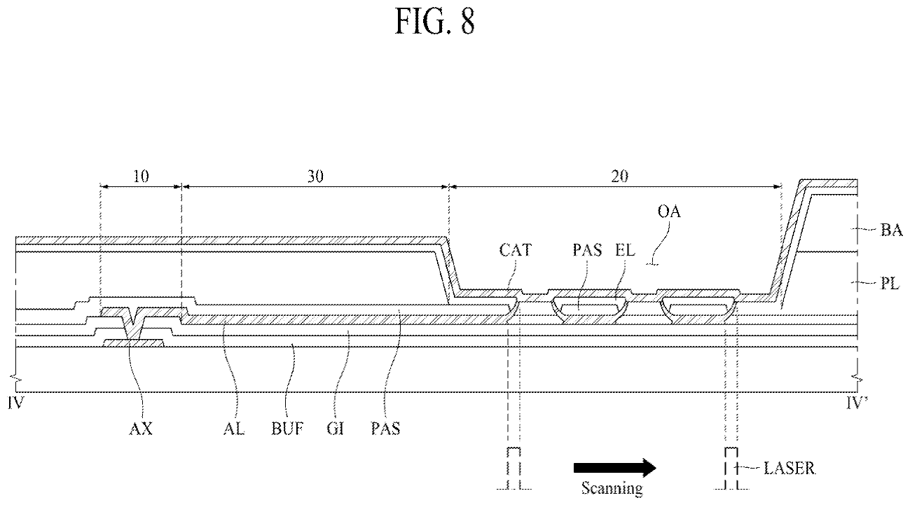

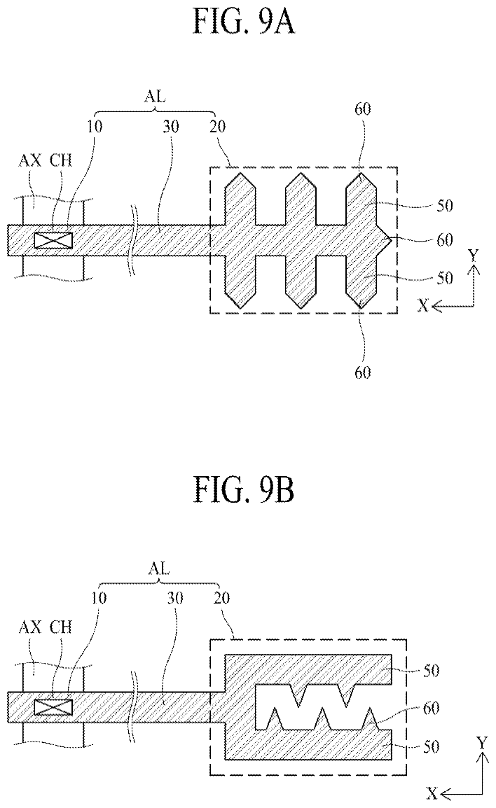

Hereinafter, referring to FIGS. 6 to 8, a structure of a light emitting display device according to a second aspect of the present disclosure will be described. FIG. 6 is an enlarged plan view illustrating a structure of one pixel disposed in a light emitting display device according to a second aspect of the present disclosure. FIG. 7 is a cross-sectional view, along cutting line III-III′ in FIG. 6, illustrating a structure of one pixel in the light emitting display device according the second aspect of the present disclosure. FIG. 8 is a plan view, along cutting line IV-IV′ in FIG. 6, illustrating a structure of a connection part between a common electrode and an auxiliary electrode in the light emitting display device according to the second aspect of the present disclosure.

Referring to FIGS. 6 to 8, the light emitting display device according to the second aspect of the present disclosure comprises a plurality of pixels P on a substrate 110. One pixel P is defined by a scan line SL, a data line DL and a driving current line VDD. One pixel P of the light emitting display device includes a switching thin film transistor ST, a driving thin film transistor DT, a light emitting diode OLE and a storage capacitance Cst. The driving current line VDD is supplied with a high-potential voltage for driving the light emitting diode OLE.

The switching thin film transistor ST may be configured to be connected to the scan line SL and the data line DL. The switching thin film transistor ST includes a gate electrode SG, a source electrode SS and a drain electrode SD. The gate electrode SG may be formed as a part of the scan line SL. The source electrode SS is branched from or connected to the data line DL, and the drain electrode SD is connected to the driving thin film transistor DT. The switching thin film transistor ST is operated as to apply a data signal to the driving thin film transistor DT to select a pixel to be driven.

The driving thin film transistor DT serves to drive the light emitting diode OLE of the pixel selected by the switching thin film transistor ST. The driving thin film transistor DT includes a gate electrode DG, a source electrode DS and a drain electrode DD. The gate electrode DG of the driving thin film transistor DT is connected to the drain electrode SD of the switching thin film transistor ST. As for the driving thin film transistor DT, the drain electrode DD is branched or connected to the driving current line VDD, and the source electrode DS is connected to the anode electrode ANO of the light emitting diode (or light emitting element) OLE. A capacitor Cst may be formed between the gate electrode DG of the driving thin film transistor DT and the anode electrode ANO of the light emitting diode OLE.

The driving thin film transistor DT is disposed between the driving current line VDD and the light emitting diode OLE. The driving thin film transistor DT controls the amount of electric current flowing from the driving current line VDD to the light emitting diode OLE according to the voltage difference between the gate electrode DG and the source electrode DS of the driving thin film transistor DT.

The light emitting diode OLE includes an anode electrode ANO, and emission layer EL and a cathode electrode CAT. The light emitting diode OLE emits light according to the current controlled by the driving thin film transistor DT. In other words, the light emitting diode OLE may display an image by emitting light according to the current controlled by the driving thin film transistor DT. The anode electrode ANO of the light emitting diode OLE is connected to the source electrode DS of the driving thin film transistor DT, and the cathode electrode CAT is connected to the low-voltage line VSS to which the low-potential voltage is supplied. That is, the light emitting diode OLE is driven by the current flowing from the driving current line VDD to the low-power line VSS by the driving thin film transistor DT.

A plurality of pixels P is disposed on the substrate 110. For example, a red pixel, a green pixel and a blue pixel may be consecutively arranged in the horizontal direction. A red pixel, a green pixel and a blue pixel may form one of unit pixel. As another example, a red pixel, a green pixel, a white pixel and a blue pixel may be continuously arranged in the horizontal direction. In FIG. 6, only one of pixel P of a red pixel, a green pixel and a blue pixel is shown.

One of pixel P of the light emitting display device according to the second aspect includes an emission area EA and a transmission area TA. The emission area EA is an area where the anode electrode ANO of the light emitting diode OLE is disposed. The transmission area TA is a transparent area, and is an area where external light incident from the lower portion of the substrate 110 is transmitted as it is and goes out to upper portion of the substrate 110. A scan line SL may be disposed in the transmission area TA. To increase transmittance, it may have a structure in which opaque elements are disposed as little as possible.

An auxiliary electrode AL may be disposed in the transmission area TA. The auxiliary electrode AL may be formed of a metal material. To increase transmittance of the transmission area TA, the auxiliary electrode AL may be formed of a transparent conductive material. When the auxiliary electrode AL is formed of a transparent conductive material, resistance of the auxiliary electrode AL may be reduced by widening the width or width of the auxiliary electrode AL.

Referring to FIG. 6, the emission area EA may be disposed between the driving current line VDD and the auxiliary line AX. As shown in FIG. 6, the emission area EA may overlap with the driving current line VDD and the auxiliary line AX. A transmissive area TA may be disposed between an auxiliary line and a driving current line VDD of neighboring pixel P.

Further referring to FIG. 7, a cross-sectional structure of a light emitting display device according to a second aspect will be described. The light emitting display device according to the second aspect includes a substrate 110, a driving element layer 220 and a light emitting element layer 330. The driving element layer 220 includes multilayer thin films formed on the substrate 110. The driving element layer 220 includes a switching thin film transistor ST and a driving thin film transistor DT.

In detail, a data line DL, a driving current line VDD, an auxiliary line AX and a light shielding layer LS are formed on the substrate 110. The light shielding layer LS may be formed in an island shape spaced apart from the data line DL and the driving current line VDD by a predetermined distance and overlapping with the semiconductor layers SA and DA.

A buffer layer BUF is stacked to cover the entire surface of the substrate 110 on the driving current line VDD, the auxiliary line AX, the data line DL and the driving current line VDD. A semiconductor layer SA of the switching thin film transistor ST and a semiconductor layer DA of the driving thin film transistor DT are formed on the buffer layer BUF. The channel area of the semiconductor layers SA and DA may overlap with the light shielding layer LS.

A gate insulating layer GI is stacked on the substrate 110 on which the semiconductor layers SA and DA are formed. A gate electrode SG overlapping with the semiconductor layer SA of the switching thin film transistor ST and a gate electrode DG overlapping with the semiconductor layer DA off the driving thin film transistor DT are formed on the gate insulating layer GI. In addition, on both sides of the gate electrode SG of the switching thin film transistor ST, a source electrode SS contacting one side of the semiconductor layer SA and a drain electrode SD contacting the other side of the semiconductor layer SA, while being spaced apart from the gate electrode SG, are formed. Similarly, on both sides of the gate electrode DG of the driving thin film transistor DT, a source electrode DS contacting one side of the semiconductor layer DA and a drain electrode DD contacting the other side of the semiconductor layer DA, while being spaced apart from the gate electrode DG, are formed.

The gate electrodes SG and DG and the source-drain electrodes SS, SD, DS and DD are formed on the same layer, but are spatially or electrically separated from each other. In addition, the source electrode SS of the switching thin film transistor ST is connected to the data line DL through a contact hole penetrating the gate insulating layer GI. Similarly, the drain electrode DD of the driving thin film transistor DT is connected to the driving current line VDD through another contact hole penetrating the gate insulating layer GI.

A passivation layer PAS is stacked on the substrate 110 on which the thin film transistors ST and DT are formed. The passivation layer PAS may be formed of an inorganic material such as silicon oxide or silicon nitride.

A light emitting element layer 330 is formed on the driving element layer 220. The light emitting element layer 330 includes a light emitting diode OLE. Before forming the light emitting diode OLE, a planarization layer PL is stacked on the passivation layer PAS. The planarization layer PL is a thin film for flattening the top surface of the substrate 110 on which the thin film transistors ST and DT are formed when the top surface of the substrate 110 is not even condition. To make the height difference uniform, the planarization layer PL may be formed of an organic material. A pixel contact hole PH exposing a part of the source electrode DS of the driving thin film transistor DT is formed at the passivation layer PAS and the planarization layer PL.

An anode electrode ANO is formed on an upper surface of the planarization layer PL. The anode electrode ANO is connected to the source electrode DS of the driving thin film transistor DT through the pixel contact hole PH. Components of the anode electrode ANO may vary according to the light emitting structure of the light emitting diode OLE. For example, in the case of a bottom emission type that provides light in the direction of the substrate 110, the anode electrode ANO may be formed of a transparent conductive material. For another example, when the light is emitted in an upward direction facing the substrate 110, the anode electrode ANO may be formed of a metal material having excellent light reflectance. Since the present disclosure relates to a top emission type display device, the anode electrode ANO may include a metal material.

A bank BA is formed on the surface of the substrate 110 on which the anode electrode ANO is formed. The bank BA may be an insulating layer made of an inorganic material or an organic material. Here, a case in which the bank BA is made of an organic material will be described. The bank BA covers a part of the edge of the anode electrode ANO, exposing most of the central portions. A central portion not covered by the bank BA is defined as an emission area EA, and an area in which the bank BA is formed is defined as a non-emission area NEA. In addition, a transmission area TA may be disposed between the emission area EA and the non-emission area NEA.

An emission layer EL is stacked on the anode electrode ANO and the bank BA. The emission layer EL may be formed over the entire display area AA of the substrate 110 to cover the anode electrode ANO and the bank BA. The emission layer EL according to an example may include at least two emission parts for generating white light. For example, the emission layer EL may include a first emission part and a second emission part vertically stacked for generating white light by mixing the first light from the first emission part and the second light from the second emission part. When the emission layer EL emits white light, the emission layer EL may be deposited on the emission area EA and the transmission area TA.

For another example, the emission layer EL may include any one of a blue emission part, a green emission part, and a red emission part for generating light corresponding to a color set in each pixel. Further, the light emitting diode OLE may include a functional layer for improving light emitting efficiency and/or lifetime of the emission layer EL. When the emission layer EL emits any one of red light, green light and blue light, the emission layer EL may be selectively formed only in the emission area EA.

A cathode electrode CAT is deposited on the entire surface of the substrate 110 on which the emission layer is formed. The cathode electrode CAT is deposited to make surface contact with the emission layer EL. The cathode electrode CAT is formed over the entire substrate 110 to be commonly connected to the emission layer EL deposited in all pixels. In the case of the top emission type, the cathode electrode CAT may include a transparent conductive material. For example, the cathode electrode CAT may be made of a transparent conductive material such as indium-tin-oxide (ITO) or indium-zinc-oxide (IZO).

In the top emission type, the metal oxide, which is a transparent conductive material configuring the cathode electrode CAT, has a sheet resistance considerably higher than that of the metal material. Therefore, a structure that lowers the resistance of the cathode electrode CAT is required. The auxiliary line AX is an element for lowering the resistance of the cathode electrode CAT. The auxiliary line AX may be formed first on the surface of the substrate 110, and the cathode electrode CAT may be formed last after other layers are formed. Therefore, an element for connecting the auxiliary line AX and the cathode electrode CAT is required.

Referring to FIGS. 6 and 8, a structure of the auxiliary electrode AL, which is an element for connecting the auxiliary line AX and the cathode electrode CAT, and a structure of the connection area A for connecting the cathode electrode CAT to the auxiliary electrode AL will be explained. The auxiliary line AX may be disposed to overlap with the pixel P. The auxiliary line AX does not need to be arranged for each pixel P. For example, one auxiliary line AX may be disposed for every 3-, 6- or 12-pixels P in the horizontal direction. As shown in FIG. 6, the auxiliary line AX may overlap with the emission area EA of the pixel P, and may be disposed adjacent to the data line DL. The auxiliary line AX may be arranged not to overlap with the transmission area TA so as not to affect the transmittance of the transmission area TA.

A buffer layer BUF and a gate insulating layer GI are sequentially deposited on the auxiliary line AX as covering entire surface of the substrate 110. A contact hole CH exposing portions of the auxiliary line AX is formed at the gate insulating layer GI and the buffer layer BUF. An auxiliary electrode AL is formed on the gate insulating layer GI. The auxiliary electrode AL may include a line connection part 10 and an electrode connection part 20. The line connection part 10 is a portion overlapping with the auxiliary line AX. The electrode connection part 20 may extend from the line connection part 10 to overlap with the transmission area TA. In this case, an extension part 30 connecting the line connection part 10 and the electrode connection part 20 may be further provided. The line connection part 10 of the auxiliary electrode AL is in physical and electrical contact with the auxiliary line AL through the contact hole CH.

The auxiliary electrode AX may be formed of the same material on the same layer as the gate electrode SG and DG, and/or the source-drain electrodes SS-SD and DS-DD. The auxiliary electrode AL may be formed of a material such as copper (Cu), aluminum (Al), molybdenum (Mo), and titanium (Ti) or mixture thereof, and may have a thickness of at least 5,000 Å. A passivation layer PAS is deposited on the auxiliary electrode AL. A planarization layer PL is deposited on the passivation layer PAS. The portion where the auxiliary electrode AL is formed may be patterned and removed, that is, the portion of the planarization layer PL covering the electrode connection part 20.

An anode electrode ANO is formed on the planarization layer PL. The auxiliary electrode AL is disposed at the transmission area TA which is apart from the anode electrode ANO with a predetermined distance. Therefore, the anode electrode ANO is not formed over the auxiliary electrode AL, so that the anode electrode ANO does not overlap with the auxiliary electrode AL.

A bank BA is formed on the anode electrode ANO. Portions of the bank BA where the electrode connection part 20 of the auxiliary electrode AL is formed may be patterned and removed. As a result, the planarization layer PL and the bank BA may have an opening OA exposing the electrode connection part 20 of the auxiliary electrode AL.

An emission layer EL is deposited on the bank BA. The emission layer EL is commonly deposited over whole pixels P disposed on the substrate 110. Therefore, the emission layer EL is deposited at the opening OA exposing the auxiliary electrode AL. The emission layer EL is stacked on the auxiliary electrode AL.

A cathode electrode CAT is deposited on the emission layer EL. The cathode electrode CAT is also commonly deposited over the entire pixels P disposed on the substrate 110. Therefore, the cathode electrode CAT is stacked on the auxiliary electrode AL.

By irradiating a laser beam LASER on the connection part A where the electrode connection part 20 is disposed under this state, the auxiliary electrode AL is connected to the cathode electrode CAT. Here, the laser may be irradiated to the edge portions of the auxiliary electrode AL at the connection part A. The passivation layer PAS stacked on the edge of the auxiliary electrode AL may be deposited thinner than other portions. As a result, a seam portion in which the passivation layer PAS stacked on the stepped portion of the auxiliary electrode AL is relatively thinner than other portions is formed.

With this condition, when a laser is irradiated to the circumference portions of the auxiliary electrode AL, the circumference portions of the auxiliary electrode AL melted by the laser, even having a low energy, passes through the passivation layer PAS and the light emitting layer EL in sequence, and then the circumference portions of the auxiliary electrode AL may be connected to the cathode electrode CAT. For example, even when a laser having a low power, for example, having a wavelength of 532 nm or 1064 nm wavelength is irradiated, circumference portions of the auxiliary electrode AL may be melted and connected to the cathode electrode CAT. At that time, the laser may be irradiated only to both end portions of the auxiliary electrode AL, or may be scanned from one end portion to the other end portion of the auxiliary electrode AL. Since the circumference portions of the auxiliary electrode AL is only to be melted instead of all portions of the auxiliary electrode AL, the scanning process may be performed with high speed, thus the manufacturing tack time may be shortened.

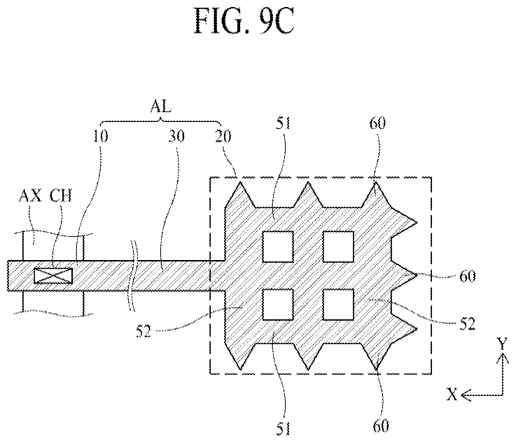

Referring to FIGS. 9A, 9B and 9C, various structures of the electrode connection part 20 of the auxiliary electrode AL according to the present disclosure will be explained. FIGS. 9A, 9B and 9C are plan views illustrating various shapes of auxiliary electrodes in the light emitting display device according to the present disclosure.

At first, referring to FIG. 9A, an auxiliary electrode AL according to the present disclosure includes a line connection part 10, an electrode connection part 20 and an extension part 30. The line connection part 10 overlaps with the auxiliary electrode AL. The line connection part 10 contacts the auxiliary electrode AL through a contact hole CH penetrating the buffer layer BUF and the gate insulating layer GI.

The electrode connection part 20 is spaced apart from the line connection part 10 by a predetermined distance. The electrode connection part 20 is a portion for electrically connecting to the cathode electrode CAT, and is disposed at a position that does not overlap with the anode electrode ANO.

The extension part 30 is an element for connecting the line connection part 10 to the electrode connection part 20. The line connection part 10, the electrode connection part 20 and the extension part 30 may be formed of one metal layer. For example, the line connection part 10, the electrode connection part 20 and the extension part 30 may be formed of the same material on the same layer as the gate electrode SG and DG. Alternatively, the line connection part 10, the electrode connection part 20 and the extension part 30 may be formed of the same material on the same layer as the source-drain electrodes SS-SD and DS-DD. Referring to FIG. 8 of the present disclosure, the gate electrodes SG and DG and the source-drain electrodes SS-SD and DS-DD are formed of the same material on the same layer. Therefore, the line connection part 10, the electrode connection part 20 and the extension part 30 may be formed of the same material on the same layer as the gate electrodes SG and DG and the source-drain electrodes SS-SD and DS-DD. However, it is not limited thereto. For another example, the gate electrodes SG and DG may be formed of a different material on a layer different from that of the source-drain electrodes SS-SD and DS-DD. In this case, an intermediate insulating layer may be interposed between the gate electrodes and the source-drain electrodes.

The electrode connection part 20 may include a plurality of lines branched from the line connection part 10 (or from the extension part 30) along the first direction to be parallel to each other. For example, as shown in FIG. 9A, the electrode connection part 20 may include three short segments 50 branched from the line connection part 10 in the Y-axis direction. Although not shown in the drawings, the electrode connection part 20 may include a plurality of line segments branched the line connection part 10 in a second direction crossing the first direction. The ends of each line segment may have a pointed shape. For example, the electrode connection part 20 may include at least one first line segment 50 branching from the line connection part 10 in the Y-axis direction. Further, the electrode connection part 20 may include at least one second line segment 60 extending from the extension part 30 in the X-axis direction. In addition, the ends of each line segments may have a triangular shape to have a pointed shape.

A plurality of line segments disposed at the electrode connection part 20 is elements for forming more circumferential edge areas of the auxiliary electrode AL. As the number of circumferential edge areas increases and/or the number of pointed portions increases, more portions connected to the cathode electrode CAT pass through the passivation layer PAS and the emission layer EL by the laser irradiation process.

Next, referring to FIG. 9B, the auxiliary electrode AL according to the present disclosure includes a line connection part 10, an electrode connection part 20 and an extension part 30. The line connection part 10 overlaps with the auxiliary line AX. The line connection part 10 contacts the auxiliary line AX through a contact hole CH penetrating the buffer layer BUF and the gate insulating layer GI.

The electrode connection part 20 is spaced apart from the line connection part 10 by a predetermined distance corresponding to the length of the extension part 30. The electrode connection part 20 is a part for electrically connecting to the cathode electrode CAT, so the electrode connection part 20 is disposed at a position that does not overlap with the anode electrode ANO. The extension part 30 is an element for connecting the line connection part 10 to the electrode connection part 20. The line connection part 10, the electrode connection part 20 and the extension part 30 may be formed of one metal layer.

The electrode connection part 20 may include a plurality of line segments branched from the line connection part 10 (or from the extension part 30) in the first direction to be parallel to each other. The electrode connection part 20 may include two or more line segments 50 branched from the extension part 30 in the first (X-axis) direction and a plurality of protrusions 60 extruding from the line segments 50 along the second (Y-axis) direction. The protrusion 60 may be formed in a triangular shape so that its tip is pointed. The protrusions 60 between two or more line segments 50 face each other and may be configured to have a shape like an alligator clip by arranged as to be staggered.

For example, as shown in FIG. 9B, the electrode connection part 20 includes two line segments 50 which are branched from the extension part 30 in the X-axis direction. Further, each line segment 50 has three protrusions 60 extruding to the Y-axis direction.

The plurality of line segments 50 and the protrusions 60 disposed at the electrode connection part 20 are elements for ensuring more edge areas of the auxiliary electrode AL which will connect to the cathode electrode CAT. As the number of circumferential edge areas increases and/or the number of pointed portions increases, more portions connected to the cathode electrode CAT pass through the passivation layer PAS and the emission layer EL by the laser irradiation process.

Finally, referring to FIG. 9C, the auxiliary electrode AL according to the present disclosure includes a line connection part 10, an electrode connection part 20 and an extension part 30. The line connection part 10 overlaps with the auxiliary line AX. The line connection part 10 contacts the auxiliary line AX through a contact hole CH penetrating the buffer layer BUF and the gate insulating layer GI.

The electrode connection part 20 is spaced apart from the line connection part 10 by a predetermined distance corresponding to the length of the extension part 30. The electrode connection part 20 is a part for electrically connecting to the cathode electrode CAT, so the electrode connection part 20 is disposed at a position that does not overlap with the anode electrode ANO. The extension part 30 is an element for connecting the line connection part 10 to the electrode connection part 20. The line connection part 10, the electrode connection part 20 and the extension part 30 may be formed of one metal layer.

The electrode connection part 20 may have a polygonal band shape having a predetermined width. For example, as shown in FIG. 9C, the electrode connection part 20 may have a shape in which four quadrangles arrayed in a 2×2 matrix manner with a predetermined width, or overlapping with each other with a predetermined width. In FIG. 9C, bands having a certain width are arranged to have a ‘ [symbol] ’ (‘window’ or ‘cross in box’) shape. In detail, three horizontal segments 51 and three vertical segments 52 may be disposed as crossing each other. Pointed protrusion 60 in a triangular shape may be disposed at each end of the horizontal segments 51. Likewise, pointed protrusion 60 in a triangular shape may be further disposed at each end of the vertical segments 52. In FIG. 9C, the pointed protrusions 60 are arranged at regular intervals, but are not limited thereto. Alternatively, the pointed protrusions 60 may be continuously arranged at one side of the vertical segment 52.

The plurality of segments 51 and 52 and the protrusions 60 configuring the electrode connection part 20 are elements for ensuring more circumferential edge areas of the auxiliary electrode AL. As the number of circumferential edge areas increases and/or the number of pointed portions increases, more portions connected to the cathode electrode CAT pass through the passivation layer PAS and the emission layer EL by the laser irradiation process.

The features, structures, effects and so on described in the above example aspects of the present disclosure are included in at least one example aspect of the present disclosure, and are not necessarily limited to only one example aspect. Furthermore, the features, structures, effects and the like explained in at least one example aspect may be implemented in combination or modification with respect to other example aspects by those skilled in the art to which this disclosure is directed. Accordingly, such combinations and variations should be construed as being included in the scope of the present disclosure.

It will be apparent to those skilled in the art that various substitutions, modifications, and variations are possible within the scope of the present disclosure without departing from the spirit and scope of the present disclosure. Therefore, it is intended that aspects of the present disclosure cover the various substitutions, modifications, and variations of the present disclosure, provided they come within the scope of the appended claims and their equivalents. These and other changes may be made to the aspects in light of the above detailed description. In general, in the following claims, the terms used should not be construed to limit the claims to the specific example aspects disclosed in the specification and the claims, but should be construed to include all possible aspects along with the full scope of equivalents to which such claims are entitled. Accordingly, the claims are not limited by the disclosure.

What is claimed is:

1. A light emitting display device comprising:
a substrate; and
a plurality of pixels disposed on the substrate,
each of the plurality of pixels includes:
a first electrode disposed at one portion of the pixel;
an emission layer disposed on the first electrode;
a second electrode disposed on the emission layer;
an auxiliary electrode close to the first electrode in the pixel; and
an auxiliary line connecting the auxiliary electrode and overlapping with a portion of the first electrode,
wherein the auxiliary electrode is connected to the second electrode by penetrating the emission layer.

2. The light emitting display device according to claim 1, wherein the auxiliary electrode includes:
a line connection part connected to the auxiliary line; and
an electrode connection part extended from the line connection part to one side of the auxiliary line, and connected to the second electrode.

3. The light emitting display device according to claim 2, wherein the electrode connection part has a polygonal band shape.

4. The light emitting display device according to claim 2, wherein the electrode connection part includes a plurality of line segments branched from the line connection part in a first direction or a second direction.

5. The light emitting display device according to claim 4, wherein the plurality of line segments includes:
at least two segments running to the first direction; and
a plurality of protrusions extruding from the segments in the second direction.

6. The light emitting display device according to claim 3, wherein one end portion of the auxiliary electrode is connected to the second electrode at the electrode connection part.

7. The light emitting display device according to claim 1, further comprising:
a first lines running to a first direction on the substrate;
a first insulating layer disposed on the first lines;
a second lines running to a second direction crossing the first direction on the first insulating layer;
a thin film transistor connected to one of the first line and one of the second line on the first insulating layer; and
a second insulating layer covering the first lines, the second lines and the thin film transistor,
wherein the first electrode is disposed on the second insulating layer and connected to the thin film transistor.

8. The light emitting display device according to claim 7, wherein the auxiliary line is one of the first lines,
wherein the auxiliary electrode is formed of a same material on a same layer of one of a gate electrode, a source electrode and a drain electrode, and
wherein the auxiliary electrode in connected to the auxiliary line via a contact hole penetrating the first insulating layer.

9. The light emitting display device according to claim 8, wherein the emission layer and the second electrode are commonly disposed over the plurality of the pixels, and
wherein the auxiliary electrode is connected to the second electrode by penetrating the second insulating layer and the emission layer.

10. The light emitting display device according to claim 1, wherein the substrate has a transparent material,
wherein each of the plurality of pixels includes:
an emission area overlapping with the first electrode; and
a transmissive area around the first electrode.

11. The light emitting display device according to claim 10, wherein the emission layer and the second electrode are disposed at the emission area and the transmissive area,
wherein the auxiliary electrode is disposed at the transmissive area and is connected to the second electrode by penetrating the emission layer at the transmissive area.

12. The light emitting display device according to claim 10, wherein the emission area further includes a thin film transistor disposed under the first electrode and connected to the first electrode, and
wherein the transmissive area passes through lights incident from a lower side of the substrate to an upper side of the substrate.

13. A light emitting display device comprising:
a substrate;
an auxiliary line on the substrate;
a first insulating layer on the auxiliary line;
an auxiliary electrode overlapping with a portion of the auxiliary line on the first insulating layer;
a second insulating layer on the auxiliary electrode;
a first electrode disposed on the second insulating layer, the first electrode not overlapping with the auxiliary electrode;
an emission layer disposed on the first electrode; and
a second electrode disposed on the emission layer, the second electrode covering the auxiliary line and the auxiliary electrode,
wherein an end portion of the auxiliary electrode not overlapping with the auxiliary line is connected to the second electrode by penetrating the second insulating layer and the emission layer.

14. The light emitting display device according to claim 13, further comprising a planarization layer disposed between the second insulating layer and the first electrode, and not overlapping with the auxiliary electrode.

15. The light emitting display device according to claim 14, further comprising a bank covering circumference area of the first electrode on the planarization layer, and not overlapping with the auxiliary electrode.

16. The light emitting display device according to claim 15, further comprising a light emitting element including the first electrode exposed by the bank, the emission layer on the first electrode, and the second electrode on the emission layer and the first electrode.

17. The light emitting display device according to claim 16, wherein the auxiliary electrode includes a plurality of segments, and
wherein edges of the plurality of segments are melted and connected to the second electrode.

18. The light emitting display device according to claim 17, wherein each of the plurality of segments has a pointed end shape.
